(19) United States
(12) Patent Application Publication
(10) Pub. No.: US 2026/0187317 A1
(43) Pub. Date: Jul. 2, 2026

(54) GARDEN DESIGN METHOD, DEVICE AND STORAGE MEDIUM BASED ON IMAGE GENERATION MODEL

(71) Applicant: Hangzhou Ruisheng Software Co., Ltd., Zhejiang (CN)

(72) Inventors: Qingsong Xu, Zhejiang (CN); Tao He, Zhejiang (CN)

(73) Assignee: Hangzhou Ruisheng Software Co., Ltd., Zhejiang (CN)

(21) Appl. No.: 19/414,291

(22) Filed: Dec. 10, 2025

(30) Foreign Application Priority Data
Dec. 26, 2024 (CN) 202411932780.3

(51) Int. Cl. G06F 30/27; G06T 5/77; G06V 20/70

(52) U.S. Cl. CPC G06F 30/27; G06T 5/77; G06V 20/70

(57) ABSTRACT

Disclosed are a garden design method and device based on an image generation model, and a storage medium. The method includes, in response to acquiring a scene image of a garden from a user, performing region segmentation on the scene image to determine a scope requiring garden design as a mask image; generating a personalized design recommendation list based on at least one of preference data of the user and scene data, wherein the user selects a reference image for garden design from the design recommendation list according to expectations; and analyzing the reference image to generate a text description for the garden design, and using the scene image, the mask image, the reference image, and the text description as input conditions for the image generation model to generate a garden design effect image that meets expectations.

### CROSS-REFERENCE TO RELATED APPLICATION

This application claims the priority benefit of China application serial no. 202411932780.3, filed on Dec. 26, 2024. The entirety of the above-mentioned patent application is hereby incorporated by reference herein and made a part of this specification.

### BACKGROUND

### Technical Field

The present disclosure relates to computer vision technology, and particularly relates to a garden design method and device based on an image generation model, and a storage medium.

### Description of Related Art

Image inpainting technology directs at filling in missing parts of an image or remove unwanted objects to restore the integrity of the image. Conventional local retouching models generate content for specific regions by utilizing information from adjacent pixels. These methods primarily include optimization algorithm-based, interpolation methods, and deep learning approaches, such as convolutional neural networks. However, these methods still have limitations regarding the transition effects of the edges of the regions and the surrounding content.

In recent years, the stable diffusion model has emerged as an innovative image generation technology, achieving higher quality image synthesis through gradual addition and elimination of noise. The application of the stable diffusion model in image restoration demonstrates significant advantages. The stable diffusion model is capable of generating samples from latent space to fill in missing regions, resulting in richer and more natural image content. Moreover, by integrating contextual information, the diffusion model may better comprehend and reconstruct local patterns and details, thereby enhancing the restoration effectiveness.

Researchers have progressively provided various deep learning-based strategies tailored to different types of missing regions, integrating the advantages of local retouching models and diffusion methods to achieve more accurate and natural image restoration outcomes. The rapid development of these technologies offers extensive prospects for content creation, including home environment design.

### SUMMARY

A brief overview of the present disclosure is provided below to provide a basic understanding of some aspects of the present disclosure. However, it should be understood that this overview is not an exhaustive overview of the present disclosure. It is not intended to identify key or important parts of the present disclosure, nor is it intended to limit the scope of the present disclosure. Its purpose is merely to present some concepts of the present disclosure in a simplified form as a prelude to the more detailed description that is presented later.

According to a first aspect of embodiments of the present disclosure, a garden design method based on an image generation model is provided, including: in response to acquiring a scene image of a garden from a user, performing a region segmentation on the scene image to determine a scope subject to garden design to serve as a mask image; generating a personalized design recommendation list based on at least one of preference data of the user and scene data, wherein the user selects a reference image for garden design from the design recommendation list according to expectations; and analyzing the reference image to generate a text description for garden design, and using the scene image, the mask image, the reference image and the text description as input conditions for the image generation model to generate a garden design effect image that meets the expectations.

In some embodiments, the region segmentation includes performing image processing using an image segmentation model to automatically identify a pixel scope in the scene image that serves as a garden land.

In some embodiments, the image segmentation model performs optimization processing on an edge part of the identified garden land.

In some embodiments, the region segmentation further includes performing custom settings on the scope of the garden design based on the input of the user.

In some embodiments, the scope of the garden design is embodied in the mask image in a visualized form for the user to execute at least one of a confirmation operation or an adjustment operation.

In some embodiments, the preference data of the user includes preference labels analyzed based on historical data of the user, wherein the design recommendation list is sorted based on the preference labels.

In some embodiments, the scene data includes geographic location information and environmental condition information of the user, wherein the environmental condition information includes climate data and soil data corresponding to the geographic location information.

In some embodiments, generating, by the image generation model, the garden design effect image that meets the expectations includes: performing adaptability processing for enhancing image quality on the reference image to obtain an adaptability reference image; performing local retouching processing on the mask image based on the reference image and the text description to obtain a retouched reference image; and generating the garden design effect image based on the adaptability reference image and the retouched reference image.

In some embodiments, generating, by the image generation model, the garden design effect image that meets the expectations includes: training a prompt context as tokens of the image generation model, thereby guiding the image generation model to perform context-aware image processing, wherein a concatenated text obtained by merging the prompt context with the text description serves as a text input for the image generation model.

In some embodiments, training the prompt context includes: performing local retouching processing using the scene image with a random mask to obtain a reconstructed unmasked image, wherein the prompt context is trained such that a region edge corresponding to the random mask in the unmasked image is coordinated with the scene image.

In some embodiments, in response to the user desiring to perform design for a specific region of a garden, the prompt context is adopted to guide the image generation model to understand and generate a garden design effect image for the specific region.

In some embodiments, generating, by the image generation model, the garden design effect image that meets the expectations includes: introducing an image prompt adapter to the image generation model to convert the reference image into an additional prompt input, wherein the additional prompt input and the text description jointly serve as tokens of the image generation model.

According to a second aspect of embodiments of the present disclosure, a garden design device based on an image generation model is provided, including: a processor; and a memory storing computer-executable instructions, wherein the computer-executable instructions, when executed by the processor, enable the processor to execute the garden design method based on the image generation model.

According to a third aspect of embodiments of the present disclosure, a non-transitory computer-readable storage medium storing computer-executable instructions is provided, wherein the computer-executable instructions, when executed by a processor, enable the processor to implement the garden design method based on an image generation model.

According to a fourth aspect of embodiments of the present disclosure, a computer program product is provided, including computer-executable instructions, which when executed by a processor, enable the processor to implement the garden design method based on an image generation model.

The advantage according to the embodiments of the present disclosure lies in using optimized region segmentation technology to determine the part subject to garden design in the scene image uploaded by the user, and through intelligent screening of the user's preference labels, automatically recommending suitable design schemes to the user in combination with machine learning algorithms.

Another advantage according to the embodiments of the present disclosure lies in training learnable token Pctxt of a model as an additional task prompt concatenated with the text of the text description, in order to guide the model to focus on context information for image generation or restoration of the user-specified region, such that the transition between the region to be designed and other regions is more natural, and the overall picture has a more reasonable filling effect.

It should be understood that the above advantages do not need to be all concentrated in one or some specific embodiments, but may be partially distributed in different embodiments according to the present disclosure. Embodiments according to the present disclosure may have one or some of the above advantages, and may alternatively or additionally have other advantages.

### BRIEF DESCRIPTION OF THE DRAWINGS

Based on the following description of embodiments of the present disclosure shown in conjunction with the accompanying drawings, the foregoing and other features and advantages of the present disclosure will become clear. The accompanying drawings are incorporated herein and form a part of the specification, further serving to explain the principles of the present disclosure and enable those skilled in the art to make and use the present disclosure. Wherein:

FIG. 1 shows a flowchart of a garden design method based on an image generation model according to an embodiment of the present disclosure;

FIG. 2 shows an exemplary block diagram of an image generation model generating a garden design effect image according to some embodiments of the present disclosure;

FIG. 3 shows an exemplary diagram of input conditions when an image generation model generates a garden design effect image according to some embodiments of the present disclosure;

FIG. 4 shows an exemplary diagram of performing local retouching on a mask image of a garden scope by an image generation model according to some embodiments of the present disclosure;

FIG. 5 shows an exemplary block diagram of using a prompt context to guide a model output in an image generation model according to some embodiments of the present disclosure;

FIG. 6 shows a schematic block diagram of a diffusion model-based garden design device according to an embodiment of the present disclosure;

FIG. 7 shows an exemplary configuration of a computing device that may be implemented according to embodiments of the present disclosure.

Note that in the embodiments described below, the same reference numerals are sometimes used in common among different drawings to indicate the same parts or parts having the same function, and repeated description thereof is omitted. In some cases, similar numerals and letters are used to indicate similar items, therefore, once an item is defined in one drawing, it does not need to be further discussed in subsequent drawings.

For ease of understanding, the position, size, scope, and the like of each structure shown in the drawings and the like sometimes do not represent the actual position, size, scope, and the like. Therefore, the present disclosure is not limited to the position, size, scope, and the like disclosed in the drawings and the like.

### DESCRIPTION OF THE EMBODIMENTS

Various exemplary embodiments of the present disclosure will be described in detail below with reference to the accompanying drawings. It should be noted that: unless otherwise specifically stated, the relative arrangement of parts and steps, numerical expressions and numerical values set forth in these embodiments do not limit the scope of the present disclosure.

The following description of at least one exemplary embodiment is merely illustrative in nature and is in no way intended as any limitation to the present disclosure and its application or use. That is, the structures and methods herein are shown in an exemplary mode to illustrate different embodiments of the structures and methods in the present disclosure. However, those skilled in the art will understand that they merely illustrate exemplary modes of the present disclosure that may be used for implementation, rather than exhaustive modes. In addition, the drawings are not necessarily drawn to scale, and some features may be enlarged to show details of specific components.

Technologies, methods and device known to those of ordinary skill in the related art may not be discussed in detail, but where appropriate, such technologies, methods and device should be considered as part of the authorized specification.

The present disclosure provides a method for generating images for garden-style designs, which is based on an image inpaint model, and improves the accuracy of design recommendations by the image generation model and satisfies user preferences by analyzing historical data related to user preferences and using context-aware enhanced tokens to guide the model to generate images, while generating more reasonable filling effects in the overall picture. The method for generating garden design images according to the present disclosure will be described in detail below with reference to the accompanying drawings. It should be understood that the actual method may also include other additional steps, but in order to avoid shifting away from the key points of the present disclosure, these other additional steps are not discussed herein and are not shown in the accompanying drawings.

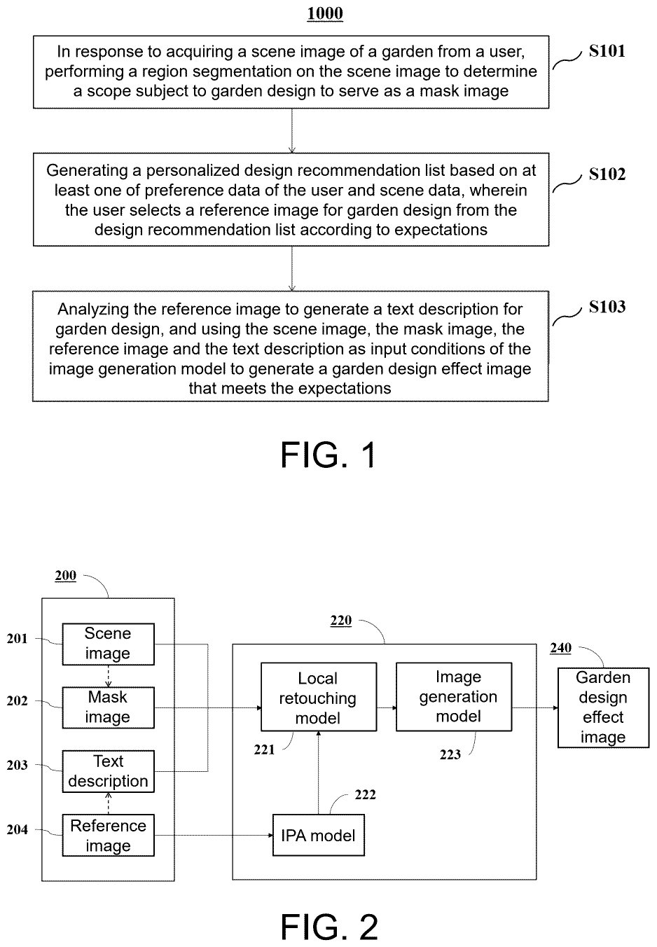

FIG. 1 shows a flowchart of a garden design method 1000 (hereinafter referred to as method 1000) based on an image generation model according to an embodiment of the present disclosure. As shown in FIG. 1, the method 1000 mainly includes:

In step S101, in response to acquiring a scene image of a garden from a user, performing a region segmentation on the scene image to determine a scope subject to garden design to serve as a mask image;

In step S102, generating a personalized design recommendation list based on at least one of preference data of the user and scene data, wherein the user selects a reference image for garden design from the design recommendation list according to expectations;

In step S103, analyzing the reference image to generate a text description for garden design, and using the scene image, the mask image, the reference image and the text description as input conditions of the image generation model to generate a garden design effect image that meets the expectations.

Specifically, step S101 mainly serves for determining the scope for performing garden design from the scene image input by the user. Generally, the user uploads an image of the overall scene where the garden to be designed is located, wherein the overall scene includes physical elements such as a courtyard where the garden is located, roads and buildings around the garden, as well as environmental elements such as time, season and weather that may be included in the image during the imaging process. In response to acquiring the scene image uploaded by the user, region segmentation technology is utilized to determine the scope for performing garden design from the scene image. In a non-limiting embodiment, the region segmentation technology uses an image segmentation model (such as a Segmentation model) to process the scene image to automatically identify the land scope that may be transformed into a garden, and the model implements efficient and precise region segmentation through performing a pixel-level classification on the input image. Additionally, the image segmentation model may also be optimized for different application scenes, such as for the pixel scope that has been identified as garden land, defects or errors may appear in pixels of an edge part, then an improved image segmentation model is utilized to perform optimization processing on the edge part to improve the accuracy of edge identification.

Additionally or alternatively, the region segmentation in step S101 may also be customized by a user input to set the scope of the garden design. In a non-limiting embodiment, the user may also customize the region to be transformed by manually drawing in the scene image. In particular, the region segmentation mode based on the user input may also serve as a supplement to an image segmentation algorithm. For example, when optimizing the edge part of the garden land as described above, if errors or mistakes are found in the identification of the edge part, the computer results may be reviewed and adjusted based on the user input. In some embodiments, the scope of the garden design is visually represented in the mask image within the scene image, such as representing the mask region with transparency, brightness, or color schemes different from the original scene image, and the user may directly interact with the mask region, such as performing a confirmation operation to confirm that the edge division of the garden is correct and/or an adjustment operation to reset the correct edge.

In some embodiments, step S102 mainly involves the operation of determining a garden design reference image. On one hand, considering the diversity of garden-design styles and the personalized preferences of users, intelligent screening may be performed through the user's preference labels to automatically recommend garden design schemes suitable for the user. Specifically, the user's preference data is acquired, including but not limited to the user's past design scheme selections, and/or historical data from the user's use of similar appearance design applications, thereby summarizing the user's preference labels for different styles based on the analysis of these historical data, and the preference labels may be set to correspond to the user's aesthetic levels, in other words, the user's preference level may be may intuitively reflected. In particular, such as when recommending suitable garden design schemes for the user as described above, a personalized design recommendation list may be generated based on the analysis of the user's historical data by machine learning algorithms, and the design recommendation list may be sorted based on the user's preference labels to ensure that users may find a garden-design style that matches their aesthetics.

Additionally or alternatively, in step S102, the personalized design recommendation list may also be generated based on the scene data. Generally, the scene data includes geographic location information and environmental condition information of the user. The geographic location information is mainly utilized to evaluate the architectural/landscape style of the geographic region where the garden to be designed is located. The environmental condition information includes at least climate data and soil data corresponding to the geographic location information, which serves to determine plant species that meet the conditions in the design, thereby ensuring that a garden design scheme adapted to the scene is provided for the user.

In some embodiments, the text description of the reference image is acquired in step S103. In order to make the design scheme more instructive and operable, a Contrastive Language-Image Pretraining (CLIP) model is adopted to analyze the selected reference image. This model is trained through the association between images and text, and may accurately capture image content and generate natural language descriptions, thereby providing more detailed design basis for garden design. Further, according to the acquired text description, the acquired text description is combined with the scene image, the mask image, and the reference image selected by the user from the design recommendation list to serve as input conditions for the image generation model, thereby generating the garden design effect image that meets user expectations.

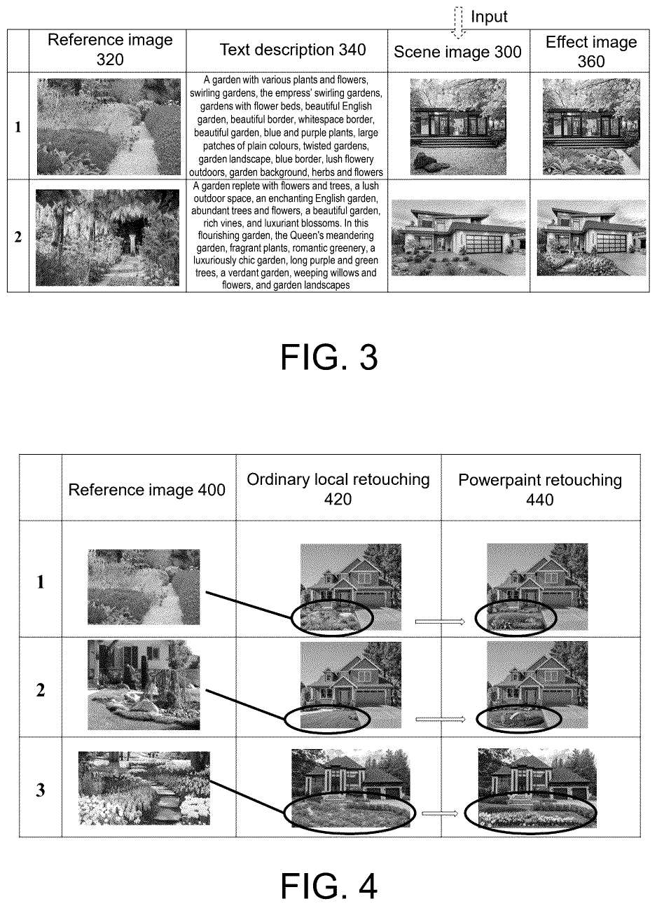

Referring next to FIG. 2, which shows an exemplary block diagram of generating garden design effect images by the image generation model according to some embodiments of the present disclosure. First, a scene image 201 is input by the user, and a mask image 202 is generated after determining the garden land scope to be designed based on region segmentation of the scene image 201. Then, the user selects a reference image 204 from the design recommendation list generated based on the user preferences and/or the scene data, and analyzes the reference image 204 to obtain a corresponding text description 203 thereof. Subsequently, input conditions 200 including the scene image 201, the mask image 202, the text description 203, and the reference image 204 are input into a garden design model 220. Specifically, the input conditions 200 for the garden design model 220 may refer to FIG. 3, which shows a garden effect image 360 obtained by sequentially processing two sets of scene images 300 input by the user.

Exemplarily, in the first set of images with serial number 1, the scene image 300 is an empty courtyard in front of a floor-to-ceiling window, a reference image 320 is a garden example including various plants, and specifically a text description 340 in natural language form is acquired from the reference image 320: “a garden with various plants and flowers, swirling gardens, the empress' swirling gardens, gardens with flower beds, beautiful English garden, beautiful border, whitespace border, beautiful garden, blue and purple plants, large patches of plain colours, twisted gardens, garden landscape, blue border, lush flowery outdoors, garden background, herbs and flowers”. As described above, region segmentation is further performed on the reference image 320 to obtain a mask image (not shown), which serves together with the scene image 300, the reference image 320, and the text description 340 as the input conditions for the image generation model 223, to ultimately generate the garden design effect image 360 of “the empty courtyard is designed to be filled with various plants”.

Referring back to FIG. 2, additionally, refined processing may also be performed for the input condition 200 respectively. In a non-limiting embodiment, generating, by the garden design model 220, the garden design effect image that meets the expectations includes performing adaptability processing for enhancing image quality on the reference image 204 to obtain an adaptability reference image. Specifically, a model such as an Image Processing Adequacy (IPA) model 222 may be adopted to process the image signal input to the garden design model 220 to obtain the adaptability reference image with enhanced image quality and details.

In another non-limiting embodiment, a local retouching model 221 may be adopted to perform local retouching processing on the mask image 202 based on the reference image 204 and the text description 203 to obtain a local retouched image. In particular, the local retouching processing may also use the adaptability reference image 204 after adaptability processing as input. Since the mask image 202 is a part of the scene image 201, the local retouching processing may be understood as performing refined processing on the local region corresponding to the mask image 202 in the scene image 201. After processing, the processed local region is combined with a part of the scene image 201 that is not masked to form a complete image corresponding to the scene image 201.

Specifically, refer to FIG. 4, which shows an exemplary diagram of performing local retouching on the mask image of the garden scope by the image generation model according to some embodiments of the present disclosure. FIG. 4 shows three sets of processes for local retouching based on a reference image 400, wherein the content within the circular frame is the garden land scope originally belonging to the scene image 201, that is, the mask region corresponding to the mask image 202. In a non-limiting embodiment, the local retouching model 221 may include an open-source Powerpaint model, which may implement a relatively good and natural retouching effect in the local retouched region. FIG. 4 shows two types of local retouching, wherein the image obtained by ordinary local retouching 420 overall looks equally consistent with the expectation of “a courtyard image with a garden (at the position corresponding to the mask region)”, while the result of Powerpaint retouching 440 overall looks more consistent with “a courtyard image with a garden, and the garden is more similar to the reference image 400”, that is, a better and more natural retouching effect may be implemented.

Continuing to refer to FIG. 2, a complete garden design effect image 240 is generated by a machine learning model including a diffusion model (such as Stable Diffusion 1.5 (SD1.5), etc.) combined with the above processing results. Based on the processing mode described above, the effect image 240 may fully consider the ecological environment for plant growth and the rationality of spatial layout while ensuring design aesthetics. Ultimately, the transfer from the reference image 204, which pertains to garden design, to the scene image 201 input by the user, and more specifically, to the region to be designed as indicated by the mask image 202 may be achieved. It should be understood that, similar to the description provided in FIG. 4, a Powerpaint model may be employed to ensure that the retouched regions and the blending edges in the design effect image 240 transition seamlessly.

In summary, the garden design method involved in the present disclosure fully utilizes image processing technology and machine learning algorithms to provide users with personalized and high-quality garden design solutions in an automated and intelligent mode.

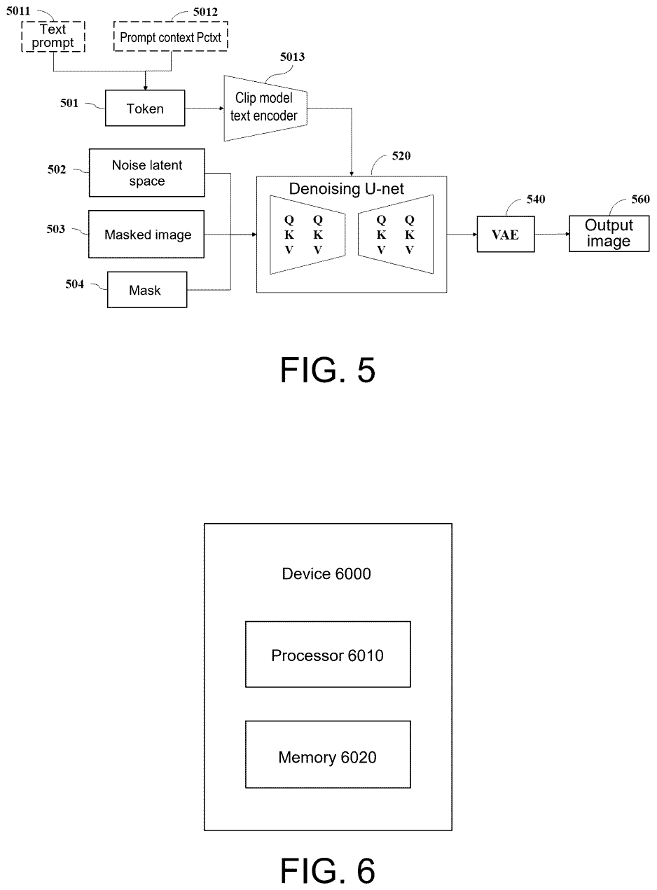

Specifically, refer to FIG. 5, which shows an exemplary block diagram of using a prompt context Pctxt to guide model output in the image generation model according to some embodiments of the present disclosure. Pctxt is trained to serve as a token 501 of the image generation model, thereby guiding the model to perform context-aware image processing, wherein Pctxt 5012 is an additional task prompt specifically employed to guide context awareness compared to the text prompt 5011 acquired from the reference image. Image generation in garden design belongs to a type used for image inpainting or image infilling, the main purpose of which is to fill the specified scope (i.e., the mask region) in the scene image in compliance with input conditions to reconstruct a completed image. However, the aforementioned conventional image inpainting models, such as sd1.5, exhibit some limitations with respect to the reasonable local inpainting and object removal. These limitations include the transition of the inpainted portions into the background outside the masked area not being sufficiently natural, among other issues.

In some embodiments, the additional task prompt Pctxt 5012 is specifically employed to guide the model to perform context-aware image processing. The learnable Pctxt 5012 enables the model to focus on filling user-specified regions according to the contextual information of the image, thereby generating repair results that blend with the surrounding image content. The training process of Pctxt 5012 may include performing local inpainting processing by the local retouching model using randomly masked regions of the scene image, and optimizing the model to obtain the reconstructed unmasked image. This training strategy encourages the model to focus on the context of the image and utilize this information to fill the missing regions, thereby producing results where the region edges of the unmasked image are coordinated with the surrounding content of the scene image. When optimizing the model, it is necessary to find the optimal Pctxt such that the model accurately predicts the noise under given input conditions, thereby making the generated image results more in line with the expectations:

$${Pctxt = {arg}_{p} min {𝔼}_{x 0 , m , t , p , ϵ t} ‖ {ϵ}_{t} - {ϵ}_{θ} ( {x}_{t}^{′} , {τ}_{θ} ( p ) , t ) ‖}_{2}^{2}$$

In the formula, t represents a denoising time step, p is randomly initialized as a set of tokens and serves as an input of a text encoder 5013 τ_{θ}(⋅); x′ₜ represents a concatenation of a noise latent space 502, a masked image 503, and a mask 504. This representation mode enables the user to seamlessly fill the mask region without explicitly specifying the required content, making the content of the image coherent with the surrounding content of the scene image.

In some embodiments, during the training process, Pctxt 5012 and text prompts 5011 obtained from other text encoders are concatenated to obtain a concatenated text, which serves as a text condition input to abase model of the sd1.5 model. It should be understood that this prompt is optimized to minimize the difference between the model output and the original image, thereby enabling the repaired region to seamlessly integrate into the surrounding image context. Further, the noise latent space 502, the mask image 503, and the mask 504 are input to a denoising u-net model 520, and the denoised image is output to a variational encoder VAE 540, ultimately obtaining an output image 560 of the garden design effect image with a higher image quality.

Additionally or alternatively, in practical application, in response to a user's desire to design for a specified location in a garden and to ensure that the design content integrates well with the surrounding environment—namely, to conduct image restoration or inpainting of a specific region within the scene image—the filled content should match the context of the surrounding scene image. This can be achieved by using Pctxt to guide the model in generating appropriate content. In a non-limiting embodiment, if a region within the scene image is masked, Pctxt may assist the model in understanding and generating content that matches the surrounding environment of that region, including but not limited to textures, colors, and styles present in the environmental context.

It should be understood that the division of steps in the flowcharts is intended solely for illustrative purposes and should not be construed as limiting the embodiments of the present disclosure. These steps may be completed individually by the illustrated entities, collaboratively by two or more entities, or in conjunction with external systems not depicted, and are not confined to the distribution methods illustrated. They may be executed sequentially in the order shown or in parallel, provided that such execution complies with the data flow direction and system operational rules, and may be performed separately or in combination.

The present disclosure also provides a garden design device 6000 based on an image generation model, which may include a processor 6010, and a memory 6020 storing computer-executable instructions. The computer-executable instructions, when executed by the processor 6010, enable the processor 6010 to execute the garden design method based on the image generation model according to any of the foregoing embodiments of the present disclosure. The processor 6010 may be a central processing unit (CPU) of the image generation device, which may be any type of general-purpose processor, or may be a processor specially designed for the garden design method based on the image generation model, such as an application specific integrated circuit (“ASIC”). The memory 6020 may include various computer-readable media accessible by the processor 6010.

The present disclosure also provides a non-transitory computer-readable storage medium storing computer-executable instructions, which, when executed by a processor, enable the processor to implement the garden design method based on the image generation model according to any of the foregoing embodiments of the present disclosure.

The present disclosure also provides a computer program product, including computer-executable instructions, wherein the computer-executable instructions, when executed by a processor, enable the processor to implement the garden design method based on the image generation model according to any of the foregoing embodiments of the present disclosure.

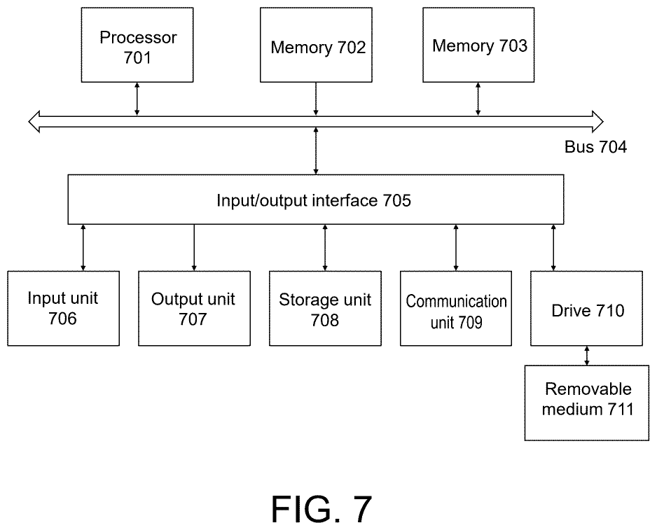

FIG. 7 shows an exemplary configuration of a computing device that may be implemented according to embodiments of the present disclosure. The computing device includes one or more processors 701, an input/output interface 705 connected to the processor 701 via a bus 704, and memories 702 and 703 connected to the bus 704. In some embodiments, the memory 702 may be a read-only memory (ROM), and the memory 703 may be a random access memory (RAM).

The processor 701 may be any kind of processor, and may include but is not limited to one or more general-purpose processors or special-purpose processors (such as special-purpose processing chips). The memory 702 and the memory 703 may be any non-transitory storage device that may implement data storage, and may include but is not limited to disk drives, optical storage devices, solid-state memory, floppy disks, flexible disks, hard disks, magnetic tape or any other magnetic medium, compact disks or any other optical medium, cache memory and/or any other storage chips or modules, and/or any other medium from which a computer may read data, instructions and/or code.

The bus 704 may include, but is not limited to, an Industry Standard Architecture (ISA) bus, a Micro Channel Architecture (MCA) bus, an Enhanced ISA (EISA) bus, a Video Electronics Standards Association (VESA) local bus, and a Peripheral Component Interconnect (PCI) bus, etc.

In some embodiments, the input/output interface 705 is connected with the following units: an input unit 706 configured by input devices such as a keyboard and a mouse for a user to input operation commands, an output unit 707 that outputs images of processing operation screens and processing results to a display device, a storage unit 708 including a hard disk drive for storing programs and various data, and a communication unit 709 including a local region network (LAN) adapter and the like and performing communication processing via a network represented by the Internet. In addition, a drive 710 is also connected, and the drive 710 reads data from and writes data on a removable storage medium 711.

Various aspects, embodiments, specific implementations or features of the foregoing embodiments may be used individually or in any combination. Various aspects of the foregoing embodiments may be implemented in software, hardware or a combination of hardware and software.

For example, the foregoing embodiments may be embodied as computer-readable code on a computer-readable medium. The computer-readable medium is any data storage device that may store data, which may be read by a computer system subsequently. Examples of the computer-readable medium include a read-only memory, a random access memory, CD-ROM, DVD, a magnetic tape, a hard disk drive, a solid state drive, and an optical data storage device. The computer-readable medium may also be distributed in network-coupled computer systems such that the computer-readable code is stored and executed in a distributed mode.

For example, the foregoing embodiments may take the form of hardware circuits. The hardware circuits may include any combination of combinational logic circuits, clock storage devices (such as floppy disks, flip-flops, latches, etc.), finite state machines, memory such as static random access memory or embedded dynamic random access memory, custom designed circuits, programmable logic arrays, etc.

In an embodiment, hardware circuits according to the present disclosure may be implemented by encoding and designing one or more integrated circuits with a hardware description language (HDL) such as Verilog or VHDL, or by using discrete circuits in combination.

The terms used herein are merely for describing particular exemplary embodiments and are not intended to limit the present disclosure. Unless the context clearly indicates otherwise, the singular forms “a” and “the” used herein are intended to include the plural forms as well. It is also to be understood that the word “include” when used herein indicates the presence of stated features, integers, steps, operations, units and/or components, but does not exclude the presence or addition of one or more other features, integers, steps, operations, units and/or components and/or combinations thereof. Furthermore, in the description of the present disclosure, the terms “first”, “second”, etc. are used for descriptive purposes only and are not to be understood as indicating or implying relative importance or order. Furthermore, in the description of the present disclosure, unless otherwise stated, “a plurality of” means two or more.

References to “embodiments” or similar expressions in this specification mean that the specific features, structures, or characteristics described in connection with the embodiment are included in at least one specific embodiment of the present disclosure. Therefore, the phrase “in embodiments of the present disclosure” and similar expressions in this specification do not necessarily refer to the same embodiment.

Those skilled in the art should know that the present disclosure may be implemented in various forms, such as a complete hardware embodiment, a complete software embodiment (including firmware, resident software, microprogram code, etc.), or may also be implemented as a software and hardware embodiment, which will be referred to as “circuit”, “module”, “unit” or “system” in the following. In addition, the present disclosure may also be implemented as a computer program product in any tangible media form, which has computer usable program code stored therein.

The related description of the present disclosure is explained with reference to flowcharts and/or block diagrams of systems, apparatuses, methods, and computer program products according to specific embodiments of the present disclosure. It may be understood that each block in each flowchart and/or block diagram, and any combination of blocks in the flowcharts and/or block diagrams, may be implemented using computer program instructions. These computer program instructions may be executed by a machine composed of a processor of a general-purpose computer or a special computer or other programmable data processing apparatus, and the instructions are processed by the computer or other programmable data processing apparatus to implement the functions or operations described in the flowcharts and/or block diagrams.

Flowcharts and block diagrams of architectures, functions, and operations that may be implemented by systems, apparatuses, methods, and computer program products according to various embodiments of the present disclosure are shown in the accompanying drawings. Accordingly, each block in the flowcharts or block diagrams may represent a module, segment, or part of program code, which includes one or more executable instructions to implement the specified logical functions. It should also be noted that, in some other embodiments, the functions described in the blocks may not be performed in the order shown in the figures. For example, two blocks shown as connected may in fact be executed simultaneously, or may in some cases be executed in the reverse order of the icons depending on the functions involved. It should also be noted that each block of the block diagrams and/or flowcharts, and combinations of blocks in the block diagrams and/or flowcharts, may be implemented by special purpose hardware-based systems, or by combinations of special purpose hardware and computer instructions, to perform specific functions or operations.

Various embodiments of the present disclosure have been described above, and the above description is exemplary, not exhaustive, and is not limited to the disclosed embodiments. Many modifications and variations will be apparent to those of ordinary skill in the art without departing from the scope and spirit of the described embodiments. The selection of terminology used herein is intended to best explain the principles of the embodiments, practical applications, or technical improvements to market technologies, or to enable other persons of ordinary skill in the art to understand the embodiments disclosed herein.

What is claimed is:

1. A garden design method based on an image generation model, comprising:
in response to acquiring a scene image of a garden from a user, performing a region segmentation on the scene image to determine a scope subject to garden design to serve as a mask image;
generating a personalized design recommendation list based on at least one of preference data of the user and scene data, wherein the user selects a reference image for garden design from the design recommendation list according to expectations; and
analyzing the reference image to generate a text description for garden design, and using the scene image, the mask image, the reference image and the text description as input conditions for the image generation model to generate a garden design effect image that meets the expectations.

2. The garden design method according to claim 1, wherein:
the region segmentation comprises performing image processing using an image segmentation model to automatically identify a pixel scope in the scene image that serves as a garden land.

3. The garden design method according to claim 2, wherein:
the image segmentation model performs optimization processing on an edge part of the identified garden land.

4. The garden design method according to claim 1, wherein:
the region segmentation further comprises performing custom settings on the scope of the garden design based on an input of the user.

5. The garden design method according to claim 4, wherein:
the scope of the garden design is embodied in the mask image in a visualized form for the user to execute at least one of a confirmation operation or an adjustment operation.

6. The garden design method according to claim 1, wherein:
the preference data of the user comprises preference labels analyzed based on historical data of the user, wherein the design recommendation list is sorted based on the preference labels.

7. The garden design method according to claim 1, wherein:
the scene data comprises geographic location information and environmental condition information of the user, wherein the environmental condition information comprises climate data and soil data corresponding to the geographic location information.

8. The garden design method according to claim 1, wherein generating, by the image generation model, the garden design effect image that meets the expectations comprises:
performing adaptability processing for enhancing image quality on the reference image to obtain an adaptability reference image;
performing local retouching processing on the mask image based on the reference image and the text description to obtain a retouched reference image; and
generating the garden design effect image based on the adaptability reference image and the retouched reference image.

9. The garden design method according to claim 1, wherein generating, by the image generation model, the garden design effect image that meets the expectations comprises:
training a prompt context as tokens of the image generation model, thereby guiding the image generation model to perform context-aware image processing, wherein a concatenated text obtained by merging the prompt context with the text description serves as a text input for the image generation model.

10. The garden design method according to claim 9, wherein training the prompt context comprises:
performing local retouching processing using the scene image with a random mask to obtain a reconstructed unmasked image, wherein the prompt context is trained such that a region edge corresponding to the random mask in the unmasked image is coordinated with the scene image.

11. The garden design method according to claim 9, wherein:
in response to the user desiring to perform design for a specific region of a garden, the prompt context is adopted to guide the image generation model to understand and generate the garden design effect image for the specific region.

12. The garden design method according to claim 1, wherein generating, by the image generation model, the garden design effect image that meets the expectations comprises:
introducing an image prompt adapter to the image generation model to convert the reference image into an additional prompt input, wherein the additional prompt input and the text description jointly serve as tokens of the image generation model.

13. A garden design device based on an image generation model, comprising:
a processor; and
a memory storing computer-executable instructions, wherein the computer-executable instructions, when executed by the processor, enable the processor to execute the garden design method based on the image generation model according to claim 1.

14. A non-transitory computer-readable storage medium storing computer-executable instructions, wherein the computer-executable instructions, when executed by a processor, enable the processor to execute the garden design method based on the image generation model according to claim 1.

15. A computer program product, comprising computer-executable instructions, wherein the computer-executable instructions, when executed by a processor, enable the processor to execute the garden design method based on the image generation model according to claim 1.
